(19) United States
(12) Patent Application Publication
(10) Pub. No.: US 2014/0216922 A1
(43) Pub. Date: Aug. 7, 2014

(54) RF DELIVERY SYSTEM WITH DUAL MATCHING NETWORKS WITH CAPACITIVE TUNING AND POWER SWITCHING

(71) Applicant: APPLIED MATERIALS, INC., Santa Clara, CA (US)

(72) Inventor: ALAN A. RITCHIE, Menlo Park, CA (US)

(73) Assignee: APPLIED MATERIALS, INC., Santa Clara, CA (US)

(21) Appl. No.: 13/761,253

(22) Filed: Feb. 7, 2013

(51) Int. Cl. C23C 14/34

(52) U.S. Cl. CPC C23C 14/345
USPC 204/192.12; 204/298.06

(57) ABSTRACT

Apparatus and method for delivering power to a substrate processing chamber may include a target and a substrate support pedestal disposed in the chamber, a pedestal impedance match device coupled between the substrate support pedestal and ground, wherein the pedestal impedance match device is configured to adjust a bias voltage on the substrate support pedestal, a target impedance match device coupled between the target and ground, wherein the target impedance match device is configured to adjust a bias voltage on the target, a switch electrically coupled to the pedestal impedance match device and the target impedance match device, a first RF power source coupled to the switch, wherein the switch is configured to direct high frequency voltage from the first RF power source to either the target or the substrate support pedestal, and a second RF power source coupled to the substrate support pedestal.

### FIELD

Embodiments of the present invention generally relate to apparatus and methods for depositing metal-containing layers on substrates using radio frequency (RF)/direct current (DC) physical vapor deposition.

### BACKGROUND

Very High Frequency (VHF) physical vapor deposition (PVD) chambers use high frequency source RF as the bulk ionization source in combination with a rotating magnetron to provide a highly ionized plasma to sputter a cathode (target) by means of a low level DC voltage.

The ratio of voltage that appears on a target electrode, a substrate pedestal electrode, and a ground chamber electrode is dependent on the ratio of the electrode areas, where the smaller electrode will have the highest voltage. So, for example, in an etch chamber where the smaller electrode is the substrate pedestal electrode, the highest voltage is developed on the substrate pedestal electrode. Thus, when a low frequency bias voltage is applied to the substrate pedestal electrode, a high voltage is developed which physically etches the film on a substrate. However in the case of PVD, it is desired to have the largest (i.e., most negative) voltage to be up on the target in order to sputter the target and to produce a low voltage/low energy deposition on the substrate.

To accomplish this, some etching processes involve lowering the VHF power supplied to the target to enable a high density plasma while reducing the sputtering voltage at low pressure. A lower RF frequency is supplied to the substrate. The combination of low VHF to the target and high RF to the wafer with low gas pressure generates a high negative bias at the wafer which results in net removal of material, or etching. However the low pressure also allows more diffusion of metal from the target to reach the wafer (i.e., additional deposition). Furthermore, this additional deposition and the plasma density generated by the VHF applied to the target are difficult to decouple using typical power source feed structures and PVD chambers.

Accordingly, the inventors have provided an improved apparatus and methods for a power source feed structure and PVD chamber incorporating same.

### SUMMARY

Methods and apparatus for delivering power to a substrate processing chamber are provided herein. In some embodiments, the apparatus may include a target and a substrate support pedestal disposed in the chamber, a pedestal impedance match device coupled between the substrate support pedestal and ground, wherein the pedestal impedance match device is configured to adjust a bias voltage on the substrate support pedestal, a target impedance match device coupled between the target and ground, wherein the target impedance match device is configured to adjust a bias voltage on the target, a switch electrically coupled to the pedestal impedance match device and the target impedance match device, a first RF power source coupled to the switch, wherein the switch is configured to direct high frequency voltage from the first RF power source to either the target or the substrate support pedestal, and a second RF power source coupled to the substrate support pedestal.

In some embodiments, an apparatus for processing a substrate in a physical vapor deposition (PVD) chamber includes a chamber body, a target disposed in the chamber body, the target comprising material to be deposited on the substrate, a substrate support pedestal disposed within the chamber body to support the substrate opposite the target during processing, a pedestal impedance match device coupled between the substrate support pedestal and ground, wherein the pedestal impedance match device is configured to adjust a bias voltage on the substrate support pedestal, a target impedance match device coupled between the target and ground, wherein the target impedance match device is configured to adjust a bias voltage on the target, a switch electrically coupled to the pedestal impedance match device and the target impedance match device, a first RF power source coupled to the switch, wherein the switch is configured to direct high frequency voltage from the first RF power source to either the target or the substrate support pedestal, and a second RF power source coupled to the substrate support pedestal.

In some embodiments, a method of processing a substrate in a physical vapor deposition chamber, the substrate having an opening formed in a first surface of the substrate and extending into the substrate towards an opposing second surface of the substrate includes applying RF power at a first VHF frequency from a first RF power source to a target comprising a metal disposed in the PVD chamber above the substrate to form a plasma from a plasma-forming gas, sputtering metal atoms from the target onto the substrate using the plasma, controlling plasma sheath voltage during sputtering process by controlling an impedance of the substrate support pedestal using a variable capacitance tuner coupled between the substrate support pedestal and ground, and redirecting RF power from the first RF power source to apply power to the substrate support pedestal at a second VHF frequency to facilitate high voltage etching of the substrate.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 depicts a flow chart for a method of depositing a metal-containing layer on a substrate in accordance with some embodiments of the present invention.

FIGS. 2A-B depict the stages of deposition in accordance with the method depicted in FIG. 1.

FIG. 3 depicts a schematic, cross-sectional view of a physical vapor deposition (PVD) chamber in accordance with some embodiments of the present invention.

FIG. 4 depicts a schematic, cross-sectional view of another physical vapor deposition (PVD) chamber in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of the present invention provide apparatus and methods to independently control a plasma density from during deposition and etch/resputtering processes in a PVD chamber. Specifically, in PVD chambers that operate in dual modes of deposition and etch, embodiments of the present invention advantageously provide power delivery apparatus and methods that use the same VHF generator for delivering power to either the target or pedestal via a high power/frequency switch. In addition, the plasma sheath voltage for a deposition process may be further controlled by a variable impedance to ground matching device coupled to the substrate support pedestal disposed in the PVD chamber, while the plasma sheath voltage for an etch process may be further controlled by a variable impedance to ground matching device coupled to a target disposed in the PVD chamber.

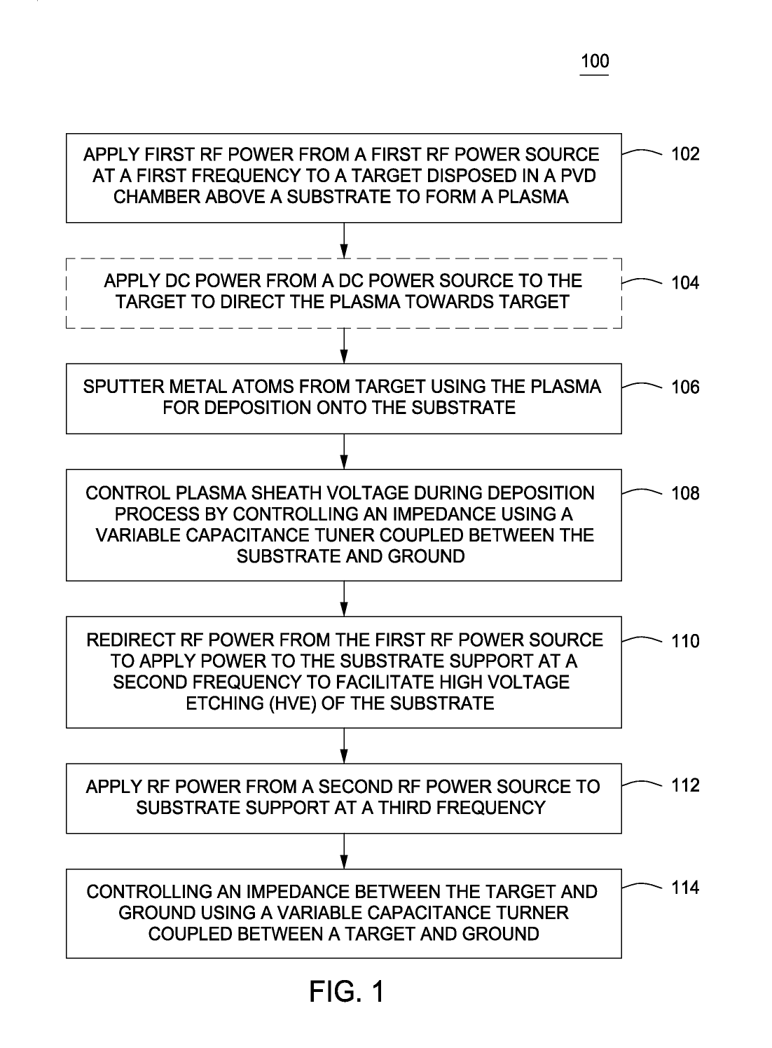

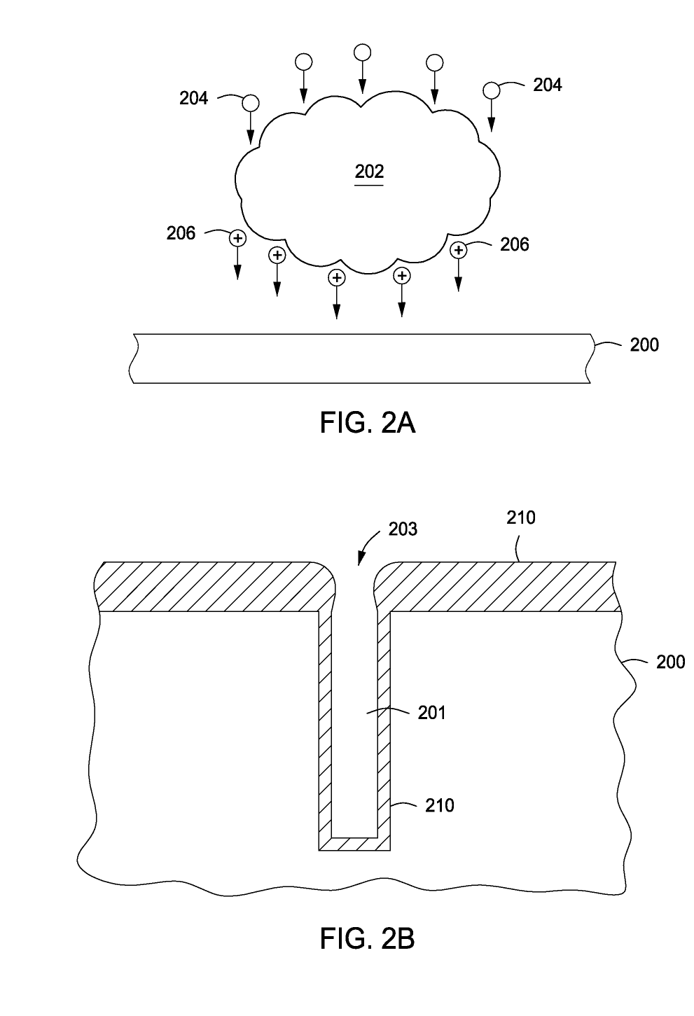

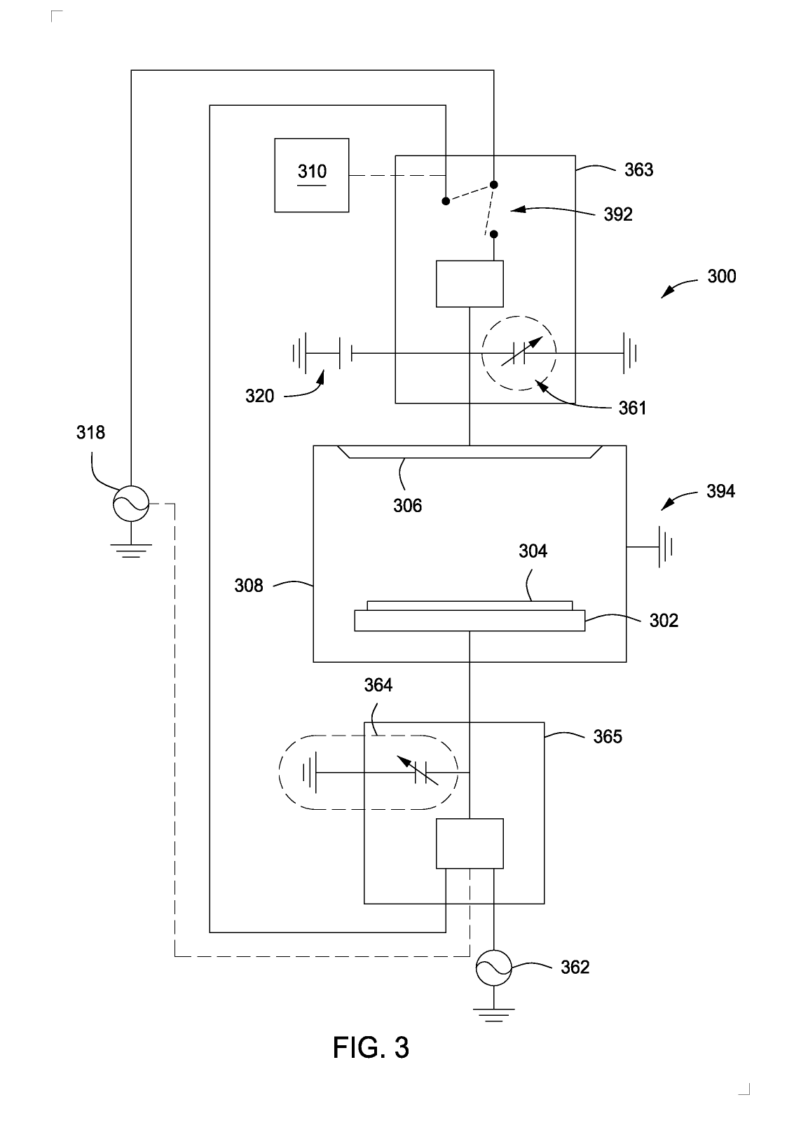

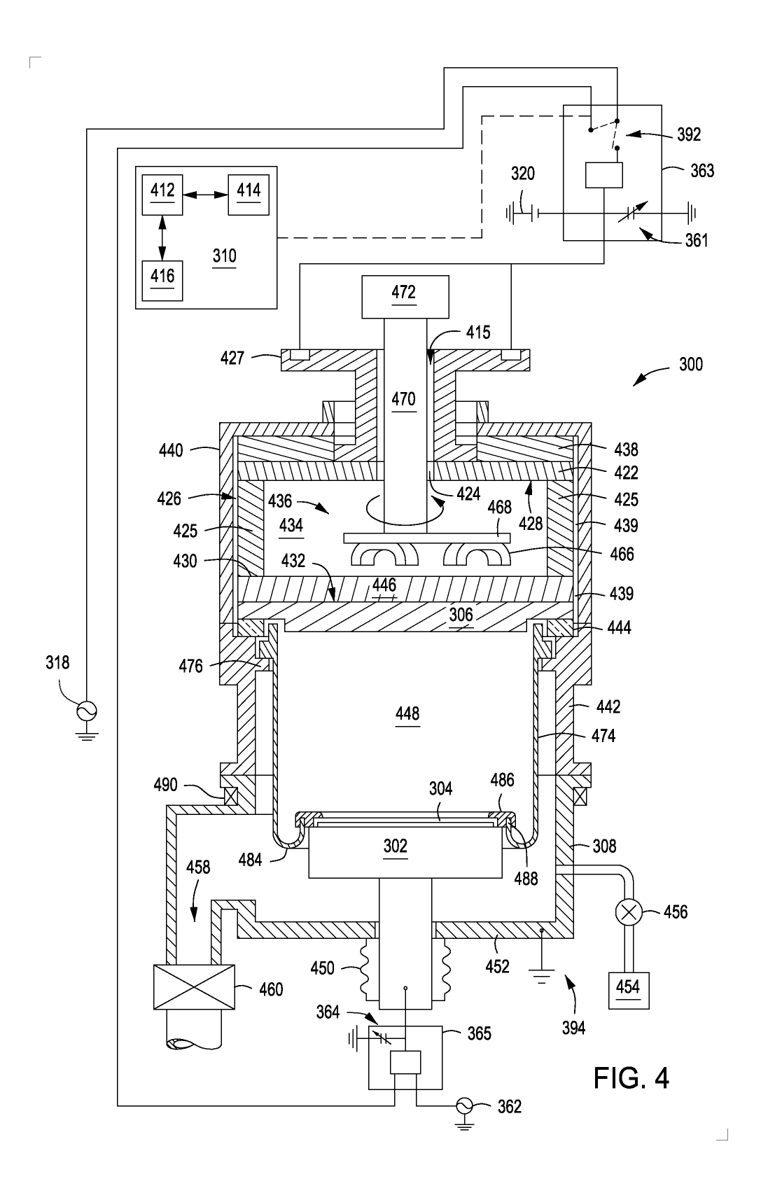

FIG. 1 depicts a flow chart of a method 100 for processing a substrate in accordance with some embodiments of the present invention. The method 100 is described below with respect to the stages of depositing a metal-containing layer as depicted in FIG. 2. The method 100 may be performed in any suitable PVD process chamber having both DC and radio frequency (RF) power sources, such as process chamber 300, described below and depicted in FIGS. 3 and 4.

The method 100 generally begins by providing a substrate 200 as shown in FIG. 2A to a PVD chamber, for example the process chamber 300. The substrate may include a blank substrate, such as having no features disposed thereon as illustrated in FIG. 2A. Alternatively, the substrate 200 may have features such as vias, trenches, or the like. In some embodiments the features may include a high aspect ratio feature 201 for, for example, as used in through silicon via (TSV) applications or the like, and as illustrated in FIG. 2B. As used herein, a high aspect ratio feature includes those features having a height to width aspect ratio of at least about 5:1. The substrate 200 may comprise one or more of silicon (Si), (SiO₂), (SiN), or other dielectric materials, such as low k dielectric materials (i.e., k≦3.9), for example, such as ultra low k dielectric materials (i.e., k≦2.5). Further, the substrate 200 may comprise one or more of metals, metal alloys, or the like.

At 102, RF power (such as from an RF power source 318, described below) is applied at a VHF frequency to a target comprising metal disposed above the substrate 200 to form a plasma 202 from a plasma-forming gas. The target may be the target 306 discussed below. Further, the target may comprise one or more of metals, metal alloys, or the like, suitable for forming a metal-containing layer on the substrate 200. For example, the target may comprise one or more of titanium (Ti), tantalum (Ta), copper (Cu), aluminum (Al), titanium nitride (TiN), aluminum nitride (AlN), aluminum oxide (Al₂O₃), cobalt (Co), tungsten (W), silicon (Si) or the like. The plasma-forming gas may include an inert gas, such as a noble gas, or other reactive gas. For example, non-limiting examples of suitable plasma-forming inert and and reactive gases may include argon (Ar), helium (He), xenon (Xe), neon (Ne), krypton (Kr), nitrogen (N₂), oxygen (O₂) or the like.

The RF power may be applied at a VHF frequency for one or more of forming the plasma from the plasma-forming gas and ionizing metal atoms sputtered from the target by the plasma. As used herein, a VHF frequency is a frequency in the range of from about 27 MHz to about 162 MHz. In some embodiments, the VHF frequency applied is about 60 MHz. Controlling the VHF frequency may facilitate control over the plasma density and/or the amount of ionization in metal atoms sputtered from the target. For example, increasing the VHF frequency may increase the plasma density and/or the amount of ionization in metal atoms sputtered from the target. The RF power applied to the target at 102 may be sufficient to sputter target material. However, optionally, at 104, DC power may also be applied to the target to increase the rate at which material can be sputtered from the target, as discussed below.

At 104, optionally, DC power may be applied to the target to direct the plasma 202 towards the target, for example, from a DC power source 320 coupled to the target 306 as described below. In some embodiments, the DC power may range from about 1 to about 2 kilowatts (kW). In some embodiments, the DC power may be about 1-5 kW, or approximately 2 kW. The DC power may be adjusted to control the deposition rate of sputtered metal atoms on the substrate. For example, increasing the DC power can result in increased interaction of the plasma with the target and increased sputtering of metal atoms from the target.

At 106, metal atoms 204 are sputtered from the target using the plasma while maintaining a first pressure in the PVD chamber sufficient to ionize a predominant portion of metal atoms being sputtered from the target. For example, a predominant portion of metal atoms may range from about 60 to about 90 percent of the total number of metal atoms being sputtered by the plasma. The first pressure, in addition to the first RF power and the DC power applied, may be dependent on process chamber geometry (such as substrate size, target to substrate distance, and the like). For example, the first pressure may range from about 6 to about 140 millitorr (mT) in a chamber configured with a target to substrate gap of about 60 to 90 millimeters (mm). In some embodiments, the first pressure is about 100 mTorr. The first pressure in the chamber may be maintained by the flow rate of the plasma-forming gas and/or the flow rate of an additional gas, such as a reactive gas, which may be co-flowed with the plasma-forming gas. The first pressure may provide a high density of gas molecules between the target and the substrate 200 with which sputtered metal atoms 204 may collide and become ionized metal atoms 206. Pressure may be additionally utilized to control the amount of ionization of metal atoms sputtered from the target. For example, increasing pressure in the target to substrate gap may increase the number of collisions with metal atoms and increase the amount of ionized metal atoms 206.

At 108, the plasma sheath voltage between the plasma and the substrate may be controlled to form a metal-containing layer 210 on one or more surfaces of the feature 201 while limiting overhang of the metal-containing layer 210 across a mouth 203 of the feature. The plasma sheath voltage may be controlled by various methods. In some embodiments, the plasma sheath voltage may be controlled by controlling impedance between the substrate and ground. For example, the chamber impedance can be controlled by a capacitance tuner coupled between the substrate support and ground, such as the capacitance tuner 364 discussed below and illustrated in FIG. 3.

At 110, after deposition of the target material onto the substrate is completed, the RF power applied to the target at VHF frequency may be redirected to apply power to the substrate support at a second frequency to facilitate high voltage etching/resputtering of the metal-containing layer 210 deposited on the substrate. In some embodiments, the second frequency is typically the same as the first frequency. In other embodiments, the first and second frequencies may be different. In some embodiments, the redirecting of the RF power applied at VHF frequency is accomplished via a high power/frequency switch disposed in a target impedance match network, such as switch 392 disposed in target impedance match network 363 discussed below and illustrated in FIG. 3. In other embodiments, redirecting of the RF power applied at VHF frequency may be done using an impendence matching device such as, for example, pedestal match device 365. For example, redirecting may be accomplished by setting the impedance of the path between RF power supply 318 and the substrate support pedestal 302 to either a high impedance or low impendence using an impendence matching device disposed between the VHF power supply and the pedestal or target. In some embodiments, the VHF frequency may be set at one or more of about 27.12, 40.68, 60, 81 or 162 MHz.

At 112, a second RF power source may apply low frequency energy (e.g., a third frequency that is different from the first and second frequencies described above) to the substrate to facilitate high voltage etching/resputtering. In some embodiments, the low frequency supplied by the second RF source may be about 2 to about 13.56 MHz. In some embodiments, the VHF power at 110 may control plasma density and stabilize the plasma sheath voltage, while the lower frequency power at 112 supplies high voltage acceleration of the material species ions doing the etching.

At 114, the plasma sheath voltage may be controlled during the high voltage etching/resputtering process by various methods. In some embodiments, the plasma sheath voltage may be controlled by controlling impedance between the target and ground. For example, the chamber impedance can be controlled by a capacitance tuner coupled between the target and ground, such as the capacitance tuner 361 discussed below and illustrated in FIG. 3. In other embodiments, the plasma sheath voltage may be controlled by controlling impedance between the substrate support and ground. The substrate support may contain an electrode that is smaller than the target electrode. Typically, controlling impedance at the smaller electrode has a greater affect on the sheath voltage. For example, the chamber impedance can be controlled by a capacitance tuner coupled between the substrate support and ground, such as the capacitance tuner 364 discussed below and illustrated in FIG. 3.

FIG. 3 depicts a schematic, cross-sectional view of an exemplary physical vapor deposition chamber (process chamber 300) in accordance with some embodiments of the present invention. Other PVD chambers may also be used with the inventive apparatus and methods disclosed herein. Examples of suitable PVD chambers are commercially available from Applied Materials, Inc., of Santa Clara, Calif. Other process chambers from other manufactures may also benefit from the inventive apparatus disclosed herein.

The process chamber 300 contains a substrate support pedestal 302 for receiving a substrate 304 thereon, and a sputtering source, such as a target 306. The substrate support pedestal 302 may be located within a grounded enclosure wall 308, which may be a chamber wall or a grounded shield.

In some embodiments, the process chamber may include an RF power source 318 to provide VHF power to either the target 306 or substrate support pedestal 302 (via switch 392 discussed below), a DC power source 320 to provide DC power to the target 306, and a second RF bias power source 362 to provide low frequency power to the substrate support pedestal 302. In some embodiments, RF energy supplied by the RF power source 318 may be a VHF frequency from about 27 MHz to about 162 MHz. For example, non-limiting frequencies of about 27 MHz, 40 MHz, 60 MHz, 81 MHz and 162 MHz (or other multiples of 13.56 MHz) can be used.

In some embodiments, the RF power supplied by the second RF bias power source 362 may range in frequency from about 0.5 MHz to about 13.56 MHz.

In some embodiments, the DC power source 320 may be utilized to apply a negative voltage, or bias, to the target 306. The power supplied by DC power source 320 depends on the process running. For example, during an Etch process, DC power would not be supplied as it is not needed. In other processes, such as deposition processes for example, the DC power is used to help sputter the target material. In some embodiments, the DC power supplied may range from 100 Watts to about 2000 Watts. In some embodiments, the DC power supplied would be about a quarter of the RF power supplied for a given process.

In some embodiments, a plurality of RF power sources may be provided (i.e., two or more) to provide RF energy in a plurality of the above frequencies to each of the target 306 or the substrate support pedestal 302. The RF and DC energy may be supplied to the target and/or substrate support pedestal via feed structures that may be fabricated from suitable conductive materials to conduct the RF and DC energy from the RF power sources 318 and 362, and the DC power source 320.

In some embodiments, the feed structure may have a suitable length that facilitates substantially uniform distribution of the respective RF and DC energy about the perimeter of the feed structure. For example, in some embodiments, the feed structure may have a length of between about 1 to about 12 inches, or about 4 inches. In some embodiments, the body may have a length to inner diameter ratio of at least about 1:1. Providing a ratio of at least 1:1 or longer provides for more uniform RF delivery from the feed structure (i.e., the RF energy is more uniformly distributed about the feed structure to approximate RF coupling to the true center point of the feed structure. The inner diameter of the feed structure may be as small as possible, for example, from about 1 inch to about 6 inches, or about 4 inches in diameter. Providing a smaller inner diameter facilitates improving the length to ID ratio without increasing the length of the feed structure.

RF power source 318 and DC power source 320 may be coupled to target 306 (via the feed structure) through target impedance match device 363. The target impedance match device 363 may be coupled to the target for adjusting voltage on the target 306 and controlling the RF bias power of the target 306. The target impedance match device 363 may include a variable capacitance tuner 362 to ground for controlling the impedance. In addition, in some embodiments, target impedance match device 363 may include a high power/frequency switch 392 that can direct VHF energy from RF power source 318 to either the target 306 (e.g., for a deposition process) or the substrate support pedestal 302 through a pedestal match device 365 (e.g., for an etch/resputtering process) as desired. Thus, as shown in FIG. 3, the target impedance match device 363 may be coupled to a pedestal match device 365. A controller 310 (discussed below in more detail) may be used to control switch 392 to direct VHF energy from RF power source 318 to either the target 306 (e.g., for a deposition process) or the substrate support pedestal 302 (e.g., for an etch/resputtering process) as desired. Although switch 392 is shown as part of target impedance match device 363, switch 392 may included in pedestal match device 365, or disposed at any point between target impedance match device 363 and pedestal match device 365.

In other embodiments, redirecting of the RF power applied at VHF frequency may optionally be done using pedestal match device 365. For example, redirecting may be accomplished by setting the impedance of the path (e.g., path 398 in FIG. 3) between RF power supply 318 and the substrate support pedestal 302 to either a high impedance or low impendence using an impendence matching device disposed between the VHF power supply and the pedestal or target.

The pedestal match device 365 may include a variable capacitance tuner 364 to ground that is coupled to the substrate support pedestal for adjusting a bias voltage on the substrate 304.

FIG. 4 depicts another schematic, cross-sectional view of an exemplary physical vapor deposition chamber (process chamber 300) that may be used with embodiments the inventive apparatus and methods disclosed herein.

The target 306 may be coupled to source distribution plate 422 via conductive member 427. The source distribution plate includes a hole 424 disposed through the source distribution plate 422 and aligned with a central opening of the feed structure. The source distribution plate 422 may be fabricated from suitable conductive materials to conduct the RF and DC energy from the feed structure. The source distribution plate 422 may be coupled to the target 406 via a conductive member 425. The conductive member 425 may be a tubular member having a first end 426 coupled to a target-facing surface 428 of the source distribution plate 422 proximate the peripheral edge of the source distribution plate 422. The conductive member 425 further includes a second end 430 coupled to a source distribution plate-facing surface 432 of the target 306 (or to the backing plate 446 of the target 406) proximate the peripheral edge of the target 306.

A cavity 434 may be defined by the inner-facing walls of the conductive member 425, the target-facing surface 428 of the source distribution plate 422 and the source distribution plate-facing surface 432 of the target 306. The cavity 434 is coupled to the central opening 415 of the body via the hole 424 of the source distribution plate 422. The cavity 434 and the central opening 415 of the body may be utilized to at least partially house one or more portions of a rotatable magnetron assembly 436 as illustrated in FIG. 4 and described further below. In some embodiments, the cavity may be at least partially filled with a cooling fluid, such as water (H₂O) or the like.

A ground shield 440 may be provided to cover the outside surfaces of the lid of the process chamber 300. The ground shield 440 may be coupled to ground, for example, via the ground connection of the chamber body. The ground shield 440 has a central opening to allow the feed structure to pass through the ground shield 440 to be coupled to the source distribution plate 422. The ground shield 440 may comprise any suitable conductive material, such as aluminum, copper, or the like. An insulative gap 439 is provided between the ground shield 440 and the outer surfaces of the distribution plate 422, the conductive member 425, and the target 306 (and/or backing plate 446) to prevent the RF and DC energy from being routed directly to ground. The insulative gap may be filled with air or some other suitable dielectric material, such as a ceramic, a plastic, or the like.

In some embodiments, a ground collar may be disposed about the body and lower portion of the feed structure. The ground collar is coupled to the ground shield 440 and may be an integral part of the ground shield 440 or a separate part coupled to the ground shield to provide grounding of the feed structure. The ground collar 440 may be made from a suitable conductive material, such as aluminum or copper. In some embodiments, a gap disposed between the inner diameter of the ground collar and the outer diameter of the body of the feed structure may be kept to a minimum and be just enough to provide electrical isolation. The gap can be filled with isolating material like plastic or ceramic or can be an air gap. The ground collar prevents cross-talk between the RF feed and the body, thereby improving plasma, and processing, uniformity.

An isolator plate 438 may be disposed between the source distribution plate 422 and the ground shield 440 to prevent the RF and DC energy from being routed directly to ground. The isolator plate 438 has a central opening to allow the feed structure to pass through the isolator plate 438 and be coupled to the source distribution plate 422. The isolator plate 438 may comprise a suitable dielectric material, such as a ceramic, a plastic, or the like. Alternatively, an air gap may be provided in place of the isolator plate 438. In embodiments where an air gap is provided in place of the isolator plate, the ground shield 440 may be structurally sound enough to support any components resting upon the ground shield 440.

The target 306 may be supported on a grounded conductive aluminum adapter 442 through a dielectric isolator 444. The target 306 comprises a material to be deposited on the substrate 304 during sputtering, such a metal or metal oxide. In some embodiments, the backing plate 446 may be coupled to the source distribution plate-facing surface 432 of the target 306. The backing plate 446 may comprise a conductive material, such as copper-zinc, copper-chrome, or the same material as the target, such that RF and DC power can be coupled to the target 306 via the backing plate 446. Alternatively, the backing plate 446 may be non-conductive and may include conductive elements (not shown) such as electrical feedthroughs or the like for coupling the source distribution plate-facing surface 432 of the target 306 to the second end 430 of the conductive member 425. The backing plate 446 may be included for example, to improve structural stability of the target 306.

The substrate support pedestal 302 has a material-receiving surface facing the principal surface of the target 306 and supports the substrate 304 to be sputter coated in planar position opposite to the principal surface of the target 306. The substrate support pedestal 302 may support the substrate 304 in a central region 448 of the process chamber 300. The central region 448 is defined as the region above the substrate support pedestal 302 during processing (for example, between the target 306 and the substrate support pedestal 302 when in a processing position).

In some embodiments, the substrate support pedestal 302 may be vertically movable through a bellows 450 connected to a bottom chamber wall 452 to allow the substrate 304 to be transferred onto the substrate support pedestal 302 through a load lock valve (not shown) in the lower portion of processing the chamber 300 and thereafter raised to a deposition, or processing position. Chamber wall 452 may connected to ground 394. One or more processing gases may be supplied from a gas source 454 through a mass flow controller 456 into the lower part of the chamber 300. An exhaust port 458 may be provided and coupled to a pump (not shown) via a valve 460 for exhausting the interior of the process chamber 300 and facilitating maintaining a desired pressure inside the process chamber 300.

A rotatable magnetron assembly 436 may be positioned proximate a back surface (e.g., source distribution plate-facing surface 432) of the target 306. The rotatable magnetron assembly 436 includes a plurality of magnets 466 supported by a base plate 468. The base plate 468 connects to a rotation shaft 470 coincident with the central axis of the chamber 300 and the substrate 304 as illustrated in FIG. 4. However, this design of the magnetron assembly is merely one exemplary embodiment. For example, other designs may include a rotatable magnetron assembly that is disposed off axis with respect to the central axis of the chamber and the substrate.

A motor 472 can be coupled to the upper end of the rotation shaft 470 to drive rotation of the magnetron assembly 436. The magnets 466 produce a magnetic field within the chamber 300, generally parallel and close to the surface of the target 306 to trap electrons and increase the local plasma density, which in turn increases the sputtering rate. The magnets 466 produce an electromagnetic field around the top of the chamber 300, and magnets 466 are rotated to rotate the electromagnetic field which influences the plasma density of the process to more uniformly sputter the target 306. For example, the rotation shaft 470 may make about 0 to about 150 rotations per minute.

In some embodiments, the chamber 300 may further include a process kit shield 474 connected to a ledge 476 of the adapter 442. The adapter 442 in turn is sealed and grounded to the aluminum chamber sidewall 308. Generally, the process kit shield 474 extends downwardly along the walls of the adapter 442 and the chamber wall 308 downwardly to below an upper surface of the substrate support pedestal 302 and returns upwardly until reaching an upper surface of the substrate support pedestal 302 (e.g., forming a u-shaped portion 484 at the bottom). Alternatively, the bottommost portion of the process kit shield need not be a u-shaped portion 484 and may have any suitable shape. In some embodiments, process kit shield 474 may be grounded. A cover ring 486 rests on the top of an upwardly extending lip 488 of the process kit shield 474 when the substrate support pedestal 302 is in its lower, loading position but rests on the outer periphery of the substrate support pedestal 302 when it is in its upper, deposition position to protect the substrate support pedestal 302 from sputter deposition. An additional deposition ring (not shown) may be used to shield the periphery of the substrate 304 from deposition. In some embodiments, a capacitance tuner (not shown) may be coupled to the process kit shield for adjusting voltage on the shield 474. The capacitance tuner (not shown) may be utilized, for example, to direct ion flow towards the shield 474 and/or in combination with the capacitance tuners 364 and/or 361 to control the energy and direction of ion flow.

In some embodiments, a magnet 490 may be disposed about the chamber 300 for selectively providing a magnetic field between the substrate support pedestal 302 and the target 306. For example, as shown in FIG. 4, the magnet 490 may be disposed about the outside of the chamber wall 308 in a region just above the substrate support pedestal 302 when in processing position. In some embodiments, the magnet 490 may be disposed additionally or alternatively in other locations, such as adjacent the adapter 442. The magnet 490 may be an electromagnet and may be coupled to a power source (not shown) for controlling the magnitude of the magnetic field generated by the electromagnet.

A controller 310 may be provided and coupled to various components of the process chamber 300 to control the operation thereof. The controller 310 includes a central processing unit (CPU) 412, a memory 414, and support circuits 416. The controller 310 may control the process chamber 300 directly, or via computers (or controllers) associated with particular process chamber and/or support system components. The controller 310 may be one of any form of general-purpose computer processor that can be used in an industrial setting for controlling various chambers and sub-processors. The memory, or computer readable medium, 434 of the controller 310 may be one or more of readily available memory such as random access memory (RAM), read only memory (ROM), floppy disk, hard disk, optical storage media (e.g., compact disc or digital video disc), flash drive, or any other form of digital storage, local or remote. The support circuits 416 are coupled to the CPU 412 for supporting the processor in a conventional manner. These circuits include cache, power supplies, clock circuits, input/output circuitry and subsystems, and the like. Inventive methods as described herein may be stored in the memory 414 as software routine that may be executed or invoked to control the operation of the process chamber 300 in the manner described herein. The software routine may also be stored and/or executed by a second CPU (not shown) that is remotely located from the hardware being controlled by the CPU 412.

While the foregoing is directed to embodiments of the present invention, other and further embodiments of the invention may be devised without departing from the basic scope thereof.

1. A apparatus for delivering power to a substrate processing chamber having a target and a substrate support pedestal disposed in the chamber, comprising:
a pedestal impedance match device coupled between the substrate support pedestal and ground, wherein the pedestal impedance match device is configured to adjust a bias voltage on the substrate support pedestal;
a target impedance match device coupled between the target and ground, wherein the target impedance match device is configured to adjust a bias voltage on the target;
a switch electrically coupled to the pedestal impedance match device and the target impedance match device;
a first RF power source coupled to the switch, wherein the switch is configured to direct high frequency voltage from the first RF power source to either the target or the substrate support pedestal; and
a second RF power source coupled to the substrate support pedestal.

2. The apparatus of claim 1, wherein the switch is part of the target impedance match device.

3. The apparatus of claim 1, wherein the switch is coupled to a controller that signals the switch to direct high frequency voltage from the first RF power source to either the target or the substrate support pedestal.

4. The apparatus of claim 1, wherein the switch is configured to direct high frequency voltage from the first RF power source to the target, and wherein the first RF power source is configured to deliver power to the target between about 27 MHz and 162 MHz.

5. The apparatus of claim 1, wherein the switch is configured to direct high frequency voltage from the first RF power source to the substrate support pedestal, and wherein the first RF power source is configured to deliver power to the substrate support pedestal between about 27 MHz and 162 MHz.

6. The apparatus of claim 1, further comprising a DC power source coupled to the target and configured to provide a bias voltage to the target.

7. The apparatus of claim 1, wherein the second RF power source provides low frequency voltage to the substrate support pedestal.

8. The apparatus of claim 1, wherein the second RF power source is configured to deliver power to the substrate support pedestal between about 0.5 MHz and 13.56 MHz.

9. The apparatus of claim 1, wherein target impedance match device includes a variable capacitance tuner to ground for controlling the impedance of the target.

10. The apparatus of claim 1, wherein pedestal impedance match device includes a variable capacitance tuner to ground for controlling the impedance of the substrate support pedestal.

11. Apparatus for processing a substrate in a physical vapor deposition (PVD) chamber, comprising:
a chamber body;
a target disposed in the chamber body, the target comprising material to be deposited on the substrate;
a substrate support pedestal disposed within the chamber body to support the substrate opposite the target during processing;
a pedestal impedance match device coupled between the substrate support pedestal and ground, wherein the pedestal impedance match device is configured to adjust a bias voltage on the substrate support pedestal;
a target impedance match device coupled between the target and ground, wherein the target impedance match device is configured to adjust a bias voltage on the target;
a switch electrically coupled to the pedestal impedance match device and the target impedance match device;
a first RF power source coupled to the switch, wherein the switch is configured to direct high frequency voltage from the first RF power source to either the target or the substrate support pedestal; and
a second RF power source coupled to the substrate support pedestal.

12. The apparatus of claim 11, wherein the switch is part of the target impedance match device.

13. The apparatus of claim 11, wherein the switch is coupled to a controller that signals the switch to direct high frequency voltage from the first RF power source to either the target or the substrate support pedestal.

14. The apparatus of claim 11, wherein the switch is configured to direct high frequency voltage from the first RF power source to the target, and wherein the first RF power source is configured to deliver power to the target between about 27 MHz and 162 MHz.

15. The apparatus of claim 11, wherein the switch is configured to direct high frequency voltage from the first RF power source to the substrate support pedestal, and wherein the first RF power source is configured to deliver power to the substrate support pedestal between about 27 MHz and 162 MHz.

16. The apparatus of claim 11, wherein target impedance match device includes a variable capacitance tuner to ground for controlling the impedance of the target.

17. The apparatus of claim 11, wherein pedestal impedance match device includes a variable capacitance tuner to ground for controlling the impedance of the substrate support pedestal.

18. A method of processing a substrate in a physical vapor deposition (PVD) chamber, the substrate having an opening formed in a first surface of the substrate and extending into the substrate towards an opposing second surface of the substrate, the method comprising:
applying RF power at a first VHF frequency from a first RF power source to a target comprising a metal disposed in the PVD chamber above the substrate to form a plasma from a plasma-forming gas;
sputtering metal atoms from the target onto the substrate using the plasma;
controlling plasma sheath voltage during sputtering process by controlling an impedance of the substrate support pedestal using a variable capacitance tuner coupled between the substrate support pedestal and ground; and
redirecting RF power from the first RF power source to apply power to the substrate support pedestal at a second VHF frequency to facilitate high voltage etching of the substrate.

19. The method claim 18, further comprising:
applying RF power from a second RF power source to the substrate support pedestal at a third frequency.

20. The method claim 18, further comprising:
controlling an impedance between the target and ground using a variable capacitance tuner coupled between a target and ground during high voltage etching of the substrate.
